(19) United States
(12) Patent Application Publication
(10) Pub. No.: US 2003/0081699 A1
(43) Pub. Date: May 1, 2003

(54) Phase detector

(76) Inventors: Hiroshi Takatori, Sacramento, CA (US); James M. Little, Sacramento, CA (US)

Correspondence Address: Pillsbury Winthrop LLP, Intellectual Property Group, 725 South Figueroa Street, Suite 2800, Los Angeles, CA, 90017-5406, US

(21) Appl. No.: 10/001,656

(22) Filed: Oct. 31, 2001

(51) Int. Cl. H03D 3/18

(52) U.S. Cl. 375/327; 375/355; 375/376

(57) ABSTRACT

A method of determining a phase error of an input signal. An input signal is received and sampled. A first value of the input signal is determined at a first instance of time, a second value of the input signal is determined at a second instance of time, and a third value of the input signal is determined at a third instance of time. The third instance of time is between the first and the second instances of time. A phase error of the input signal is determine, based on a comparison of the third value to a threshold value. The timing of the sampling is controlled to minimize the phase error.

### BACKGROUND OF THE INVENTION

1. Field of the Invention

This invention relates to the field of phase detection, and, more specifically, to a system, method, and apparatus to detect the phase of a received data signal and reduce pattern jitter of a timing recovery system.

2. Background of the Invention

Networking applications have become very popular in recent years, particularly in response to an explosion in the use and variety of networks employed in a vast array of computing environments. Accordingly, many advances have been made in the related technology in order to improve the quality of these networking systems. For example, fully integrated transceivers for T1 network channel service units (CSUs) and integrated services digital network (ISDN) primary rate interface applications are known in the art and are presently commercially available. These devices, such as the Intel LXT360 T1/E1 transceiver, are useful for networking applications, such as timing recovery in T1 network systems. However, there are obstacles that prevent such systems from providing better jitter tolerance—a desirable quality in communications networks and other networking applications. Such obstacles may include exceptionally large amplitude jitter, a wide variation in data density, large amounts of cable attenuation, and imperfect equalization.

Jitter is the general term used to describe the noise or uncertainty in the period of incoming data in a communications system. Jitter is a problem of particular import in digital communications systems. First, jitter causes a received signal to be sampled at a non-optimal sampling point. This occurrence reduces the signal-to-noise ratio at the receiver and thus limits the information rate. Second, in conventional systems, each receiver typically extracts its receive sampling clock from the incoming data signal. Jitter makes this task significantly more difficult. Third, in long-distance transmission systems, where multiple repeaters reside in a chain, jitter accumulates. That is, each receiver extracts a clock from the incoming bit stream, re-times the data, and re-transmits the data utilizing the recovered clock. Each subsequent receiver thus sees a progressively larger degree of input jitter.

When the frequency is known, the carrier signal can be sampled by a receiver to recover transmitted data. However, the phase of the carrier signal must be known in order to ensure that the data is correctly acquired from the carrier signal. For example, in a situation where a waveform, such as a sine wave, is received, the data should be sampled at the peak of the sine wave and at the trough of the sine wave. If the signal is sampled at a point away from the peak, for example, at the transition point where the voltage level of the signal is quickly decreasing, incorrect data can be acquired.

There are methods for detecting phase in the current state of the art. Typical methods are focused upon locating test points on each side of the peak or the trough of the carrier signal, each test point being located an equal distance from the respective peak or trough, and adjusting the timing of when the wave is sampled until the two test points have equal values. When such a method is used to find the peak or trough of an ideal sine wave, the peak or trough must located directly in the middle of the test points, because an ideal sine wave is symmetrical.

Such a method is suitable for determining the phase of the incoming signal provided that the incoming signal is symmetrical. However, if the incoming signal in asymmetrical, the sampling point can be incorrectly determined. For example, if the incoming data signal has a trough at −1 volt, then a peak at 1 volt, and then the next trough is located at 0 volts, the slope of the incoming signal on the side of the sine wave between −1 volt and 1 volt is greater than the slope of the wave on the side between 1 volt and 0 volts. Accordingly, determining the midpoint between two equally spaced phase detection test points having the same voltage will not yield an accurate measurement of the peak of the incoming signal.

An incoming signal can have fluctuating peaks and troughs when corrupted by distortion and noise. The source of the distortion can be caused by Inter-Symbol Interference (ISI) and jitter. Jitter is created by non-idealities in the transmitter timing generation. Jitter can be aggravated in networks with cascaded transmitters and receivers as is typically found in T1 networks. ISI is caused by the band-limited natured of electrical circuitry used to transmit and receive the signals.

Accordingly, the prior art is deficient in that multiple test points must be determined to calculate the phase of an input signal. Also, typical methods produce errors when the input signal is asymmetrical.

### BRIEF DESCRIPTION OF THE DRAWINGS

FIG. 1 illustrates a receiver according to an embodiment of the present invention;

FIG. 2 illustrates a first signal scope trace of a data signal received by the receiver according to an embodiment of the present invention;

FIG. 3 illustrates a second signal scope trace of a data signal received by the receiver according to an embodiment of the present invention;

FIG. 4 illustrates a third signal scope trace of a data signal received by the receiver according to an embodiment of the present invention;

FIG. 5 illustrates a signal eye of the data signal received by the receiver according to an embodiment of the present invention;

FIG. 6 illustrates an out-of-phase signal input to the receiver according to an embodiment of the present invention;

FIG. 7 illustrates a process by which the timing of the sampling of the data decision points may be altered to minimize the phase error according to an embodiment of the present invention; and

FIG. 8 illustrates a decision circuit according to an embodiment of the present invention.

### DETAILED DESCRIPTION

An embodiment of the present invention may be used in a receiver to determine the phase of an input carrier signal. The input carrier signal may contain a plurality of data points, or points at which the input carrier signal may be sampled to extract correct data from the signal. A phase error is detected by sampling just one test point on the input carrier signal, the test point being located between two of the data points. The timing of the sampling of data points may then be adjusted to minimize the phase error.

In order to mitigate the effects of jitter on an input signal, a Phase Locked Loop (PLL) in the receiver may track the jitter (i.e., create a clock that follow the jitter) or reject it (i.e., create a clock that does not respond to the jitter). In an embodiment of the invention, the PLL of the receiver may track low frequency jitter and reject high frequency jitter. The PLL works by measuring a phase error of the input signal with a phase detector, filtering the signal to control the frequency response of the control loop, and applying the filtered error signal to a Voltage Controlled Oscillator (VCO). The overall system has gain and negative feedback, and the overall effect is to drive the phase error toward zero.

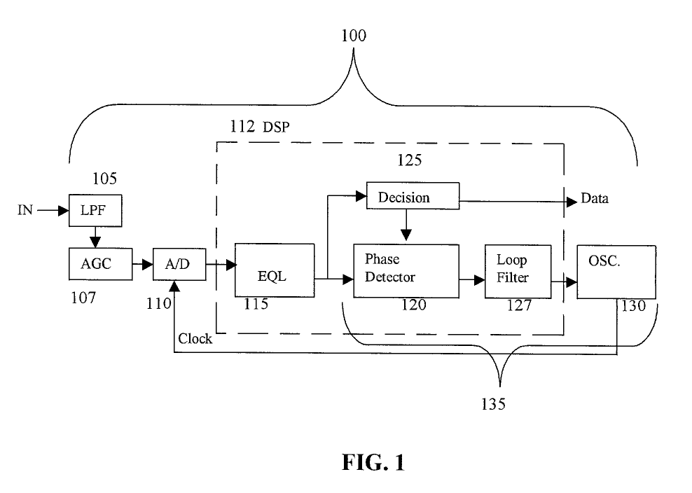

FIG. 1 illustrates a receiver 100 according to an embodiment of the present invention. An input carrier signal IN is input into the receiver 100, and then is operated on by a Low Pass Filter (LPF) 105. The filtered input signal is then output to an Automated Gain Control (AGC) 107, and is then sampled by an Analog/Digital (A/D) converter 110. Next, the input signal is fed to a Digital Signal Processor (DSP) 112. For example, the DSP 112 may include an equalizer (EQL) 115, a phase detector 120, a data decision circuit 125, and a loop filter 127.

The EQL 115 equalizes the voltage of the input signal. The EQL 115 may be a filter with a specific frequency-dependent amplitude or phase response that is used to compensate for frequency dependent amplitude and/or phase distortion in a signal. In an embodiment of the invention, the transmission media (twisted pair wire links up to 2 Km long) introduce significant distortion and attenuation in the electrical signal. The EQL 115 undoes (mostly) this distortion and restores the received signal to close to the original shape.

The processed input signal is then output to the phase detector 120, which is utilized to detect the phase of the input signal so that the input signal may be sampled at the correct point. The output of EQL 115 is also transmitted to the decision circuit 125, which extracts data from the input signal, and outputs the data to the phase detector 120 as well as to another device connected to the receiver 100, such as a Central Processing Unit (CPU), for example. The output of the phase detector 120 is then sent to the loop filter 127, which has a function of filtering the incoming signal. The carrier signal is then sent to an oscillator (OSC) 130, which is utilized to output a clocking signal so that the received carrier signal may be sampled at the correct instance. OSC 130 may be a Voltage Controlled Oscillator (VCO) or a Digitally Controlled Oscillator (DCO), for example.

The combination of phase detector 120, loop filter 127 and OSC 130 comprises a Phase Locked Loop (PLL) 135. The PLL 135 is used to track or “lock in” the phase of the input signal so that samples are taken at the correct time.

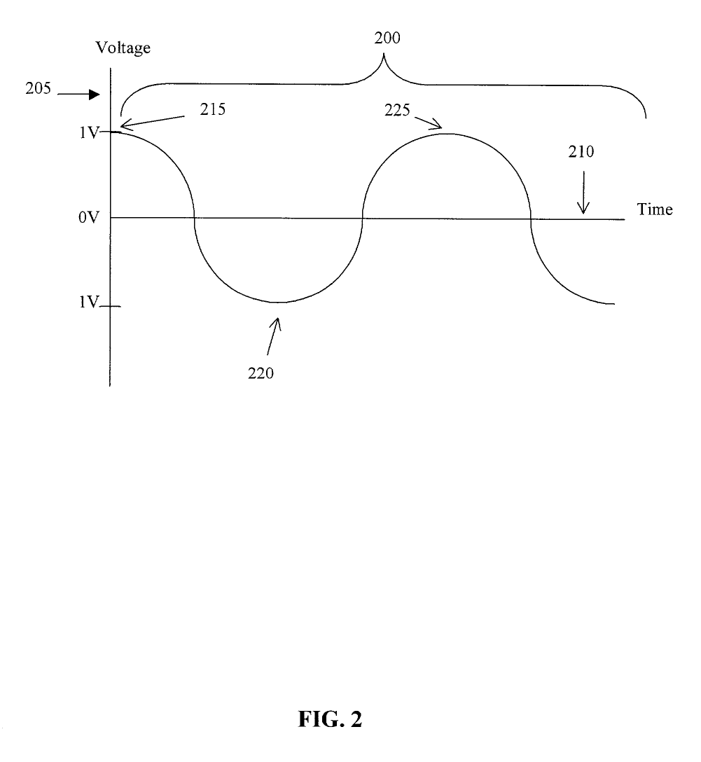

FIG. 2 illustrates a first signal scope trace 200 of a data signal received by the receiver 100 according to an embodiment of the present invention. In FIG. 2, the signal scope trace illustrates the voltage value of a data signal over a period of time. The y-axis 205 represents voltage. The x-axis 210 represents time. As illustrated, the first signal scope trace 200 depicts a waveform having a generally sinusoidal shape, with peaks 215 and 225 at “1” volt and a trough 220 at “−1” volt. At the origin of the time axis 210, the first signal scope trace 200 has a voltage value of “1.” The first signal scope trace 200 represents a carrier signal of data, and is meant to be sampled at its peaks, 215 and 225, and troughs 220. Sampling the carrier signal at a location away from a peak 215 and 225, or trough 220 can result in incorrect data being acquired.

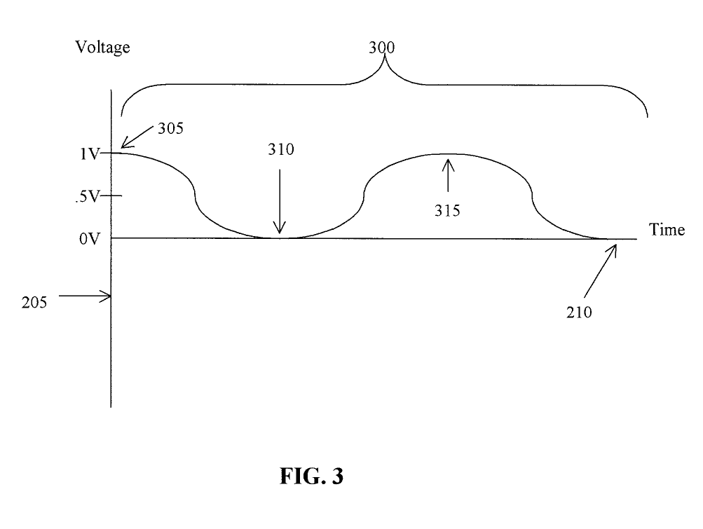

FIG. 3 illustrates a second signal scope trace 300 of a data signal received by the receiver 100 according to an embodiment of the present invention. As illustrated, the second signal scope trace 300 has peaks 305 and 315 located at “1” volt, and a trough 310 located at “0” volts. Therefore, the only voltage values represented in the second signal scope trace 300 lie between “1” and “0” volts. The second signal scope trace 300 is meant to be sampled at the peaks 305 and 315, where the voltage level is near “1”, and at a trough 310, where the voltage value is near “0.”

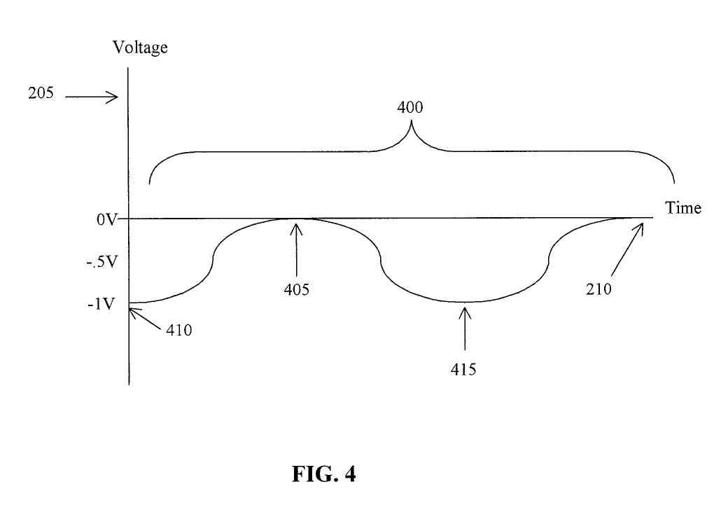

FIG. 4 illustrates a third signal scope trace 400 of a data signal received by the receiver 100 according to an embodiment of the present invention. As illustrated, the third signal scope trace 400 has a peak 405 located at “0” volts, and troughs 410 and 415 located at “−1” volts. Therefore, the only voltage values represented in the third signal scope trace 400 lie between “0” and “−1” volts. The third signal scope trace 400 is meant to be sampled at peak 405, where the voltage level is near “0” volt, and at troughs 410 and 415, where the voltage value is near “−1” volt.

The first 200, second 300, and third 400 scope traces illustrate possible carrier signals that may be received by the receiver 100. Other scope traces may also be received. According to an embodiment of the invention, in all cases, the peak of the signal scope trace are at a value of “1” or “0” volts, and the trough is at a value of “0” or “−1” volts. If a peak is located at a value of “1”, the next sampling location, (in this case, it would be the next trough) has a value of either “0” or “−1”. Similarly, if a trough is located at “−1”, the next sampling location is a peak located at “0” or “1”. In other words, if a sampling point occurs at “1” or “−1”, the next sampling point cannot be located at the same voltage level. However, if a sampling point occurs at “0”, the next sampling point may occur while the voltage is at “1”, “−1”, or “0”. In an embodiment of the invention, only the values “−1”, “0”, or “1” may be determined as data decision points. Accordingly, if the data decision point is sampled when the voltage value of the carrier signal is at “1” volt, the value of the carrier signal is determined to be “1”. However, if the carrier signal has a voltage value of “0.9” volts, when sampled, the value of the carrier signal may also be determined to be “1”. In other words, there is a range of voltages that may correspond to a “1”, for example.

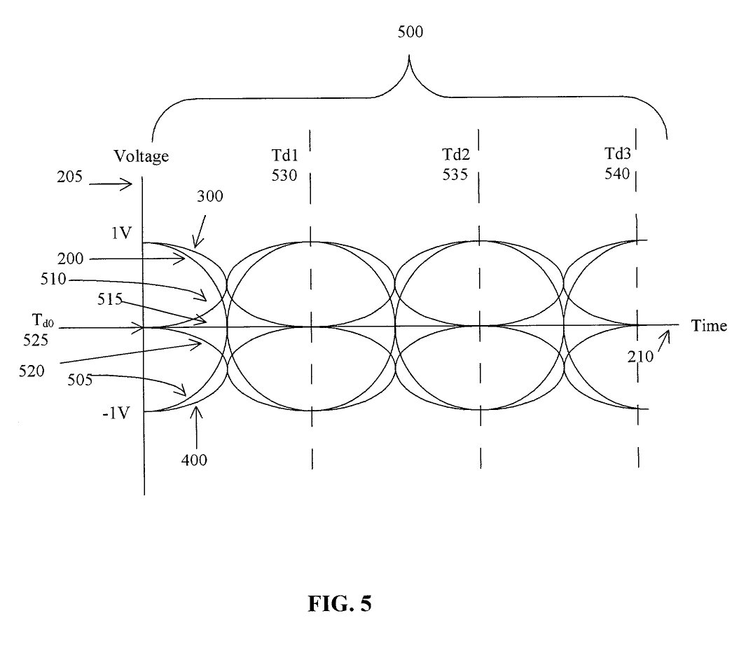

FIG. 5 illustrates a signal eye diagram 500 of the input carrier signal received by the receiver 100 according to an embodiment of the present invention. The signal eye 500 illustrates possible signal carrier waveforms. Four data decision points T_{d0} 525, T_{d1} 530, T_{d2} 535 and T_{d3} 540 are illustrated. The decision points are the ideal times at which the carrier signal should be sampled. As illustrated, there are seven waveforms between T_{d0} 525 and T_{d1} 530. One waveform, the first signal scope trace 200, is at “1” volt at T_{d0} 525, and extends down to “−1” volt at time T_{d1} 530. The second signal scope trace 300 is at “1” volt at time T_{d0} 525, and extend down to “0” volts at time T_{d1} 530. The third signal scope trace 400 is at “−1” volt at time T_{d0} 525, and extends up to “0” volts at time T_{d1} 530. A fourth signal scope 505 trace is at “−1” volts at time Td0 525, and extends up to “1” volt at time T_{d1} 530. A fifth signal scope 510 trace is at “0” volts at time Td0 525 and extends up to “1” volt at time Td1 530. A sixth signal scope trace 515 is at “0” volts at time T_{d0} 525 and is also at “0” volts at time Td1 530. Finally, a seventh signal scope trace 520 is at “0” volts at time T_{d0} 525, and extends down to “−1” volts at time T_{d1} 530.

The signal eye 500 is the superposition of signal scope traces 200, 300, 400, 505, 510, 515, 520, and 525 that exist between each of the data decision points T_{d0} 525, T_{d1} 530, T_{d2} 535, and T_{d3} 540. A jitter problem arises, for example, when the first signal scope trace 200 exists between T_{d0} 525 and T_{d1} 530, and a different scope trace exists between T_{d1} 530 and T_{d2} 535, such that the voltage value of the signal and T_{d2} 535 is different than the voltage value of the signal at time T_{d0} 525. For example, the value of the first signal scope trace 200 at T_{d0} 525 is “1”, and at T_{d1} 530 is “−1”. However, if the value of the signal is then “0” volts at T_{d2} 535, then the signal waveform is non-symmetrical (because the waveform drops “2” volts between T_{d0} 525 and T_{d1} 530, but only rises “1” volt between T_{d1} 530 and T_{d2} 535).

An embodiment of the present invention eliminates pattern jitter to improve the jitter tolerance performance of the receiver 100 and enable the equalizer 115 to maintain a low Bit Error Rate (BER) performance. The embodiment utilizes a voltage value sampled at the middle point, V_{mid}, between two data decision points, and this value is compared with a predetermined value, Vₜₕ, which is dependant upon the voltage value of the two data decision points. Vₜₕ is the voltage value of the sinusoidal waveform at the point halfway between the two data decision points. In other embodiments, Vₜₕ may be used to represent a voltage at a location other than the midpoint of between the two data decision points.

In an embodiment of the present invention, there are three possible values of Vₜₕ, depending upon the values of T_{d0} and T_{d1}. The possible values of Vₜₕ are “0.5” volts, “0” volts, and “−0.5” volts. In a situation where T_{d0} is “0” and T_{d1} is “1”, Vₜₕ would be “0.5” volts. If T_{d0} is “1” and T_{d1} is “−1”, then Vₜₕ would be “0” volts. When the system determines V_{mid}, it may calculate a phase error based upon the voltage difference between V_{mid} and Vₜₕ. In other embodiments, more than three possible values of Vₜₕ may be utilized.

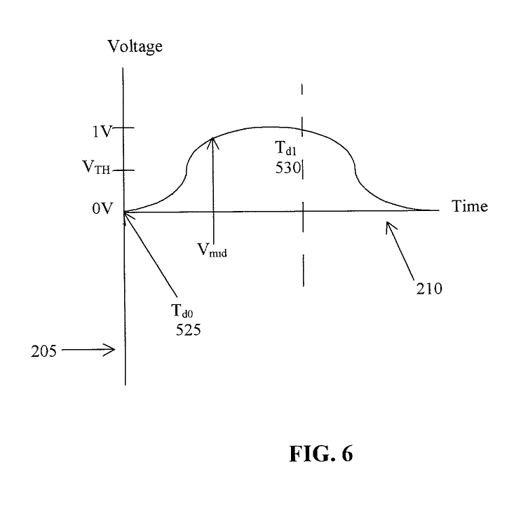

FIG. 6 illustrates an out-of-phase signal input to the receiver 100 according to an embodiment of the present invention. As shown, T_{d0} returns a value of “0” because the voltage value is near “0” at that data decision point. T_{d1} returns a value of“1” because the voltage value is near “1” at that data decision point. In this case, V_{mid} is calculated to be “0.7” volts. Since T_{d0} is “0” and T_{d1} is “1”, Vₜₕ in this case is “0.5” volts. Because Vₜₕ is not equal to V_{mid}, the system may determine that a phase error has occurred. The phase error may be determined by the following equation: Phase Error (“PE”)=SIGN(T_{d1}−T_{d0})*V_{mid}−ABS(T_{d0})*Vₜₕ+ABS(T_{d1})*Vₜₕ. SIGN returns a value of “1” for a positive values of (T_{d1}−T_{d0}), “−1” is returned for negative values, and “0” is returned when the value of (T_{d1}−T_{d0}) is “0”. ABS returns the absolute value of the operand.

According to the above equation, the PE for the waveform shown in FIG. 6 is SIGN(0-1)*(0.7 volts)−ABS(0)*(0.5 volts)+ABS(1)*(0.5 volts)=−0.2 volts. The system may then utilize the measured value of the PE to adjust the time at which T_{d0} and T_{d1} are sampled, in an effort to minimize PE. PE may be measured during each cycle of the input waveform. In other embodiments, PE may be measured periodically (e.g., once the PE is below a predetermined level, PE is measured only once every “10” cycles).

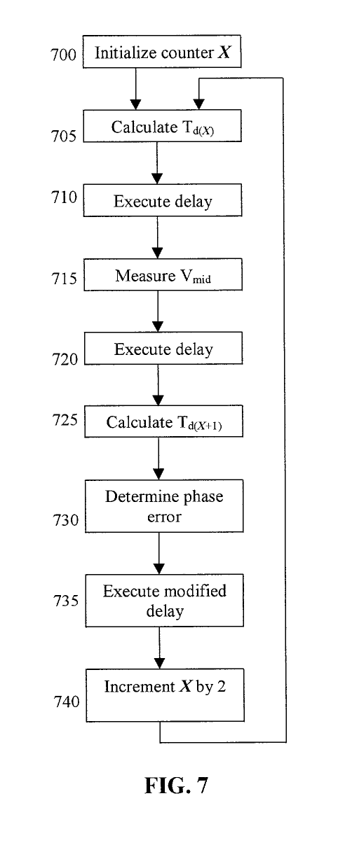

FIG. 7 illustrates a process by which the timing of the sampling of the data decision points may be altered to minimize the PE according to an embodiment of the present invention. First, counter X is initialized 700 to “0”. The value of data decision point T_{d(X)} is then determined 705 and a delay is executed 710. Next, V_{mid} is measured 715 and a delay is executed 720. Since the frequency of the received signal is typically known, the system can determine the time interval between when each data decision point should be measured. After a first data decision point is determined, V_{mid} is measured between the time at which the second data decision point is taken. At step 725, the system calculates the value of the next data decision point, T_{d(x-1)}. The phase error (PE) is then determined 730. The system then executes 735 a modified delay until the time at which the next data decision is to be determined. Finally, X is incremented 740 by “2”. Processing then returns to step 705.

If the transition from a first data decision point and a second data decision point is negative (e.g., the value of the first data decision point is “1”, and the value of the second data decision point is “0”), then a negative value of PE indicates that the data decision points are being taken too late. Accordingly, the time interval until the next data decision point is taken is decreased. If the PE had been positive, then the time interval would have been increased, because the data decision points were being taken too early. The opposite actions would be taken if the transition between the first data decision point and the second data decision point was positive.

Therefore, according to an embodiment of the invention, the phase error is calculated as the difference between one test point (i.e., V_{mid}) and one fixed value (i.e., Vₜₕ). Because only one test point (i.e., V_{mid}) is used in addition to the fixed value (i.e., Vₜₕ), the system may quickly measure a phase error and respond accordingly to reduce the phase error. Such an embodiment has a much lower phase error variance than traditional phase detectors. This is the case because only a single random variable (i.e., V_{mid}) and a fixed value (i.e., Vₜₕ) are used to calculate the phase error, rather than two random variables (i.e., two phase test points) as is done in the prior art.

The fast timing may be particularly useful for a transceiver implemented using a combination of a Analog/Digital (A/D) converter and a Digital Signal Processor (DSP). Such a DSP approach may be used to enhance a long haul analog T1 transceiver implementation to a quad or octal structure to avoid channel-to-channel cross talk in the silicon.

The output of the phase detector 120 is the measured phase error. The job of the PLL 135 is to minimize the phase error (in an ideal case, the mean of the phase error would be driven to zero). However, because of Inter-Symbol Interference (ISI) and jitter the instantaneous phase error is not zero and can be treated as a random variable. The variance (the square of the standard deviation) describes how much phase error estimate is changing over time. In a PLL 135 the phase error is filtered and applied to a VCO to create a recovered clock. If the phase error is varying a lot, but has a mean value of zero, then the recovered clock will also vary to the degree that the loop filter does not remove the phase error variations. This is generally undesirable as it creates jitter in the received clock edge. This can be related to the bit error rate (BER).

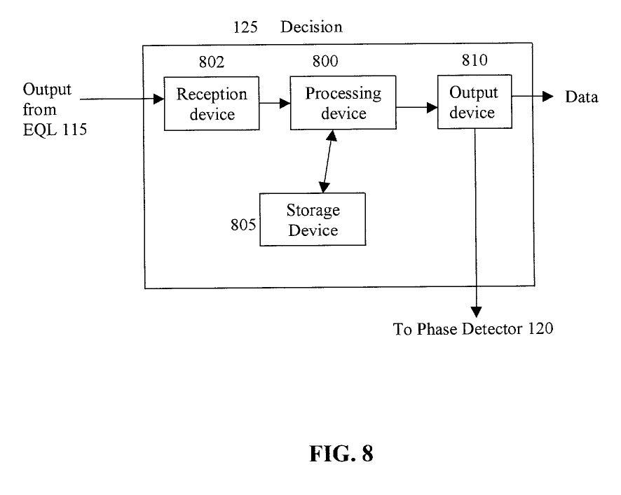

FIG. 8 illustrates a decision circuit 125 according to an embodiment of the present invention. The decision circuit 125 has the function of performing the timing method described above in FIG. 7. A reception device 802 receives the output from EQL 115. A processing device 800 acquires the each of the data points, as well as V_{mid}, and calculates Vₜₕ, and stores all of them in the storage device 805. The processing device 800 may by a Central Processing Unit (CPU), for example. Based upon the method described above with respect to FIG. 7, the processing device 800 determines the correct timing for the input signal, and outputs a phase signal to phase detector 120. An output device 810 outputs the data from the sampled data decision points.

An embodiment of the present invention may therefore detect and minimize a phase error of an input signal by measuring a minimal number of data points. For example, in the process described above in FIG. 7, when data from two decision points are known (e.g., T_{d0} and T_{d1}), only one test point, V_{mid}, needs to be measured to determine a phase error of the input signal. Therefore, the system may quickly detect and minimize the phase error.

The system can reduce the latency (i.e., the delay) between estimating the phase error and using that information to update the phase. The reason for this is because it only takes one phase information sample to estimate the pahse error, instead the of two required by methods in the prior art. This improves the ability of the PLL to track and reduce the adverse effects of incoming jitter.

While the description above refers to particular embodiments of the present invention, it will be understood that many modifications may be made without departing from the spirit thereof. The accompanying claims are intended to cover such modifications as would fall within the true scope and spirit of the present invention. The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

What is claimed is:

1. A method of determining a phase error of an input signal, comprising:
receiving the input signal;
sampling the input signal;
determining a first value of the input signal at a first instance of time;
determining a second value of the input signal at a second instance of time;
determining a third value of the input signal at a third instance of time, wherein the third instance of time is between the first and the second instances of time;
determining a phase error of the input signal, based on a comparison of the third value to a threshold value; and
controlling a timing of the sampling to minimize the phase error.

2. The method of claim 1, further including determining the threshold value based upon the first value and the second value.

3. The method of claim 1 wherein the method is performed by a Digital Signal Processing (DSP) device.

4. The method of claim 1, wherein the method is utilized to minimize effects of jitter on a determination of the first value and the second value.

5. A receiver utilized in data transmission to output data values, comprising:
an analog-to-digital converter to receive an input signal and to output a sampled digital signal;
a decision system to receive the sampled digital signal and to output at least one data value, wherein the decision system:
receives the sampled digital signal,
determines a first value of the sampled digital signal at a first instance of time,
determines a second value of the sampled digital signal at a second instance of time,
determines a third value of the sampled digital signal at a third instance of time, wherein the third instance of time is between the first instance of time and the second instance of time,
determines a phase error of the sampled digital signal based on a comparison of the third value to a predetermined threshold value, and
determines and outputs timing information;
a phase detector to receive the timing information and to output a detected phase information;
a loop filter to receive the detected phase information and to output a filtered phase information; and
an oscillator to receive the filtered phase information and to output a clock signal as a sampling clock to the analog-to-digital converter.

6. The receiver of claim 5, wherein at least the decision system is included in a Digital Signal Processor (DSP).

7. The receiver of claim 5, wherein the timing information is utilized to minimize the phase error.

8. The receiver of claim 5, wherein at least one T1 line is utilized in the data transmission.

9. A decision circuit in a receiver to output data values and detect a phase error of a sampled digital signal, comprising:
a reception device to receive the sampled digital signal, wherein the sampled signal includes at least a first value at a first instance of time, a second value at a second instance of time, and a third value at a third instance of time, wherein the third instance of time is between the first instance of time and the second instance of time;
a storage device to store the first value, the second value, and the third value;
a processing device to determine a threshold value based upon the first value and the second value, and to determine the phase error of the input signal based upon a comparison of the third value to the threshold value; and
an output device to output, the first data value, the second data value, and timing information based on the phase error.

10. The decision circuit of claim 9, wherein the decision system is included in a Digital Signal Processor (DSP).

11. The decision circuit of claim 9, wherein the timing information is utilized to minimize the phase error.

12. The decision circuit of claim 9, wherein an analog-to-digital converter converts an input signal to the sampled digital signal;

13. The decision circuit of claim 12, wherein at least one T1 line is utilized to receive the input signal.

14. A phase detection device to minimize a phase error in a sampled signal, comprising:
a computer-readable medium; and
a computer-readable program code, stored on the computer-readable medium, having instructions to
receive an input signal,
sample the input signal to create the sampled signal,
determine a first value of the input signal at a first instance of time,
determine a second value of the input signal at a second instance of time,
determine a third value of the input signal at a third instance of time, wherein the third instance of time is between the first and the second instances of time,
compare the third value to a threshold value,
determine the phase error of the input signal, and
control a timing of the sampling to minimize the phase error.

15. The phase detection device of claim 14, wherein the computer-readable program code further includes instructions to determine the threshold value based upon the first value and the second value.

16. The phase detection device of claim 14, wherein the phase detection device is included in a Digital Signal Processing (DSP) device.

17. The phase detection device of claim 14, wherein the computer-readable program code is utilized to minimize effects of jitter on a determination of the first value and the second value.
